(19) United States
(12) Patent Application Publication
(10) Pub. No.: US 2017/0103720 A1
(43) Pub. Date: Apr. 13, 2017

(54) PROTECTION OF GATE DRIVER ON PANEL OF THIN FILM TRANSISTOR ARRAY SUBSTRATE

(71) Applicant: Century Technology (Shenzhen) Corporation Limited, Shenzhen (CN)

(72) Inventors: MING-TSUNG WANG, New Taipei (TW); WEN-LIN MEI, Shenzhen (CN)

(21) Appl. No.: 14/928,711

(22) Filed: Oct. 30, 2015

(30) Foreign Application Priority Data
Oct. 12, 2015 (CN) 201510660307.9

(51) Int. Cl. G09G 3/36; H01L 27/12

(52) U.S. Cl. CPC G09G 3/3648; H01L 27/1255; G09G 2300/0426

(57) ABSTRACT

A gate driver on panel for a thin film transistor (TFT) array substrate includes a substrate, a plurality of gate drive-on-array (GOA) structures, a plurality of capacitors and a plurality of transmission lines electrically coupling the GOA structures and the capacitors together. At least one protection layer made of indium tin oxide which is electrically insulating from all of the GOA structures, the capacitors and the transmission line is formed on a top of the GOA. The at least one protection layer protects at least one of the GOA structures, the capacitors and the transmission lines from being damaged by gold balls and/or fibers in a sealant for connecting the TFT array substrate and a color filter substrate together.

### CROSS-REFERENCE TO RELATED APPLICATION

This application claims priority to Chinese Patent Application No. 201510660307.9 filed on Oct. 12, 2015, the contents of which are incorporated by reference herein.

### FIELD

The subject matter herein generally relates to a thin film transistor (TFT) array substrate, and particularly to a protection of a gate driver on panel (GOP) of the TFT array substrate from damage which may occur when the TFT array substrate is assembled with a color filter substrate.

### BACKGROUND

A TFT array substrate includes an active area for displaying images and a GOP for supplying power and signals to the active area. In manufacturing a thin film transistor liquid crystal display (TFT LCD), the GOP of the TFT array substrate is securely combined with a color filter substrate by a sealant which can contain fibers and gold balls therein. A pressure is applied on the color filter substrate toward the TFT array substrate to ensure an airtight connection between the TFT array substrate and the color filter substrate by the sealant. The pressure can cause the fibers and/or the gold balls in the sealant to enter the GOP to damage the device channels, the capacitors and/or the power/signal lines of the GOP, thereby causing the TFT array substrate to function abnormally.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

Moreover, in the drawings, like reference numerals designate corresponding parts throughout the several views.

FIG. 1 is a top view of a GOP of a TFT array substrate in accordance with a first embodiment of the present disclosure.

FIG. 2 is a cross-sectional view of a part of the GOP of FIG. 1.

FIG. 3 is a top view of a first part of a GOP of a TFT array substrate in accordance with a second embodiment of the present disclosure.

FIG. 4 is a cross-sectional view taken along line IV-IV of FIG. 3.

FIG. 5 is a top view of a second part of the GOP of the TFT array substrate in accordance with the second embodiment of the present disclosure.

FIG. 6 is a cross-sectional view taken along line VI-VI of FIG. 5.

FIG. 7 is a top view of a third part of the GOP of the TFT array substrate in accordance with the second embodiment of the present disclosure.

FIG. 8 is a cross-sectional view taken along line VIII-VIII of FIG. 7.

FIG. 9 is a table showing a scratching test of electrically conductive lines under different conditions.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

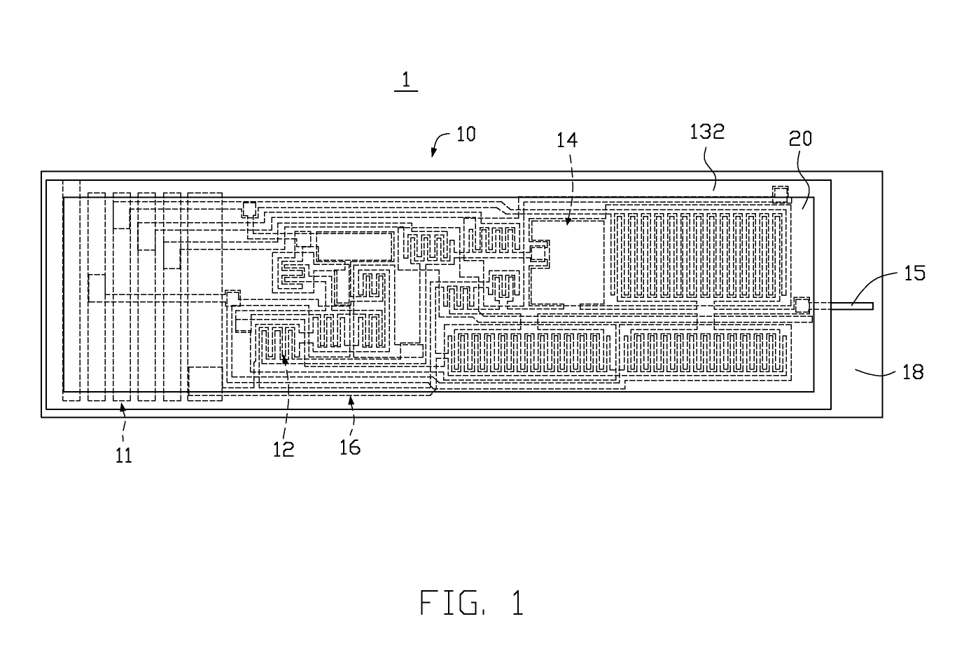

Referring to FIG. 1, a gate driver on panel (GOP) 10 of a thin film transistor (TFT) array substrate 1 includes a substrate 18, a plurality of source lines 11 formed on the substrate 18 for receiving power and signals from a driving circuitry (not shown) which can include at least one control integrated circuit (IC). The substrate 18 can be made of glass. A plurality of transmission lines 16 perpendicularly couples with the source lines 11 and extend therefrom to transmit the power and signals from the source lines 11 to a plurality of capacitors 14 and gate driver-on-array (GOA) structures 12. The capacitors 14 are provided to maintain a stable working voltage for the GOP 10. An output line 15 is provided for outputting control signals and power from the GOA structures 12 to a display area (not shown) of the TFT array substrate 1 to control on/off of thin film transistors at the display area. A protection layer 20 which is electrically conductive and can be made of indium tin oxide (ITO) is formed to cover substantially an entire top of the GOP 10. The protection layer 20 is provided to protect the transmission lines 16, the capacitors 14 and the GOA structures 12 from being damaged by fibers and/or gold balls in sealant (not shown) when the TFT array substrate 1 is securely connected with a color filter substrate (not shown) by the sealant applied between the GOP 10 and the color filter substrate.

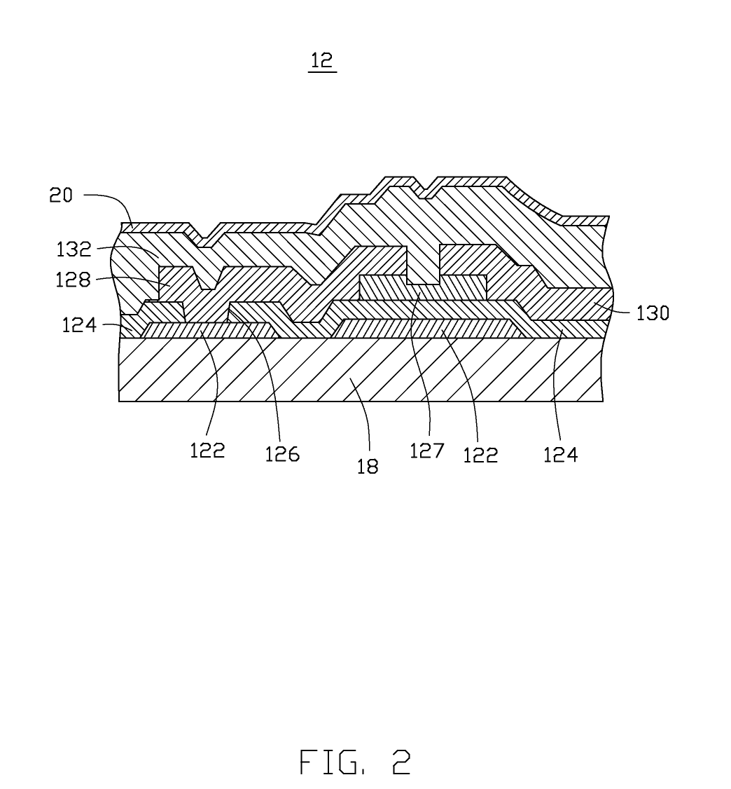

Referring to FIG. 2, each of the GOA structures 12 of the GOP 10 of FIG. 1 includes two gate electrodes 122 formed on the substrate 18. An electrically insulating layer 124 is formed on the substrate 18 to cover the two gate electrodes 122 therein. A through hole 126 is defined in the electrically insulating layer 124. An semiconductor layer 127 which can be made of amorphous silicon (a-Si) implanted with boron ions is formed on the electrically insulating layer 124 and above one of the two gate electrodes 122. A source electrode 128 and a drain electrode 130 are formed on the electrically insulating layer 124 and couple two opposite ends of the semiconductor layer 127 respectively. The gate, source and drain electrodes 122, 128, 130 can be made of metal such as aluminum for the gate electrodes 122 and gold for the source and drain electrodes 128, 130. The source electrode 128 has a portion extending downwardly into the through hole 126 to couple with the other gate electrode 122. A passivation layer 132 is formed to cover the electrically insulating layer 124, the semiconductor layer 127, the source electrode 128 and the drain electrode 130 therein. The passivaton layer 132 can be made of sputtered silicon oxide or sputtered silicon nitride. The protection layer 20 is formed on a top of the passivation layer 132. In fact, the passivation layer 132 is extended to cover substantially the entire top of the GOP 10 to cover the source lines 11, the transmission lines 16, the GOA structures 12, the capacitors 14 and the output line 15 therein. The protection layer 20 is formed substantially on an entire top of the passivation layer 132. By the design of the through hole 126 in the electrically insulating layer 124, the source electrode 128 can electrically connect with the other gate electrode 122 at a position under the passivation layer 132. Thus, the protection layer 20 will not electrically couple any two GOA structures 12 together to cause a short circuit thereof. In fact the protection layer 20 is in electrical insulation from all of the source lines 11, the GOA structures 12, the capacitors 14, the output line 15 and the transmission lines 16.

The first embodiment of the present disclosure is applicable to the GOP 10 which has all of the GOA structures 12 having the source electrodes 128 directly extending through the through holes 126 to electrically connect with the gate electrodes 122. However, for the GOP which has some GOA structures thereof relying on top ITO layers extending downwardly thorough the passivation layers and the electrically insulating layers to electrically connect the source electrodes and the gate electrodes together, the protection layer extending substantially over an entire top of the GOP is not applicable. For such GOP, the protection layer should be selectively applicable to tops of suitable GOA structures, the capacitors and the transmission lines.

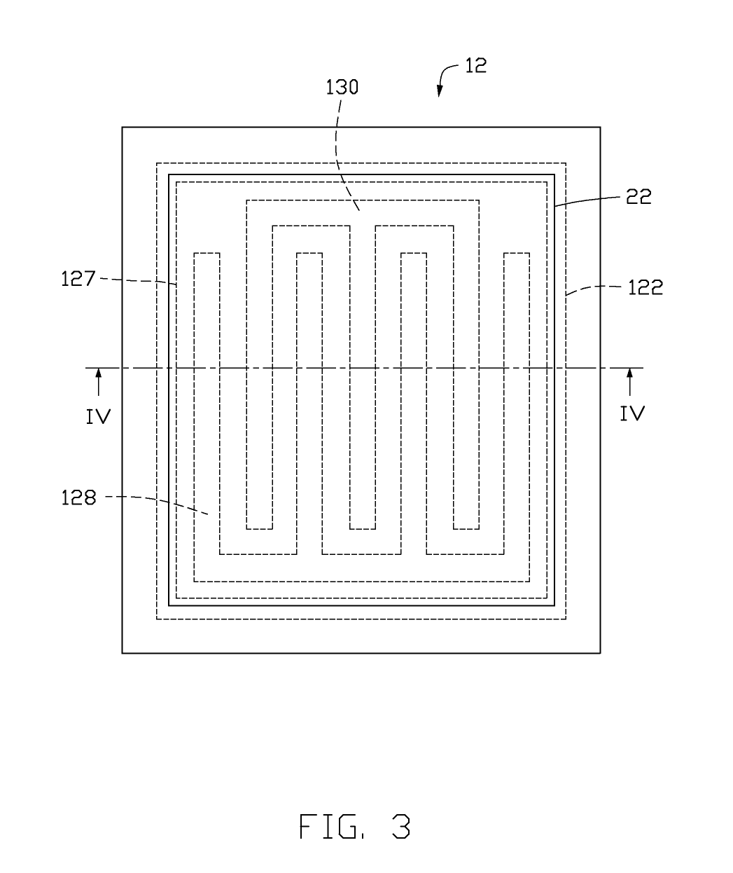

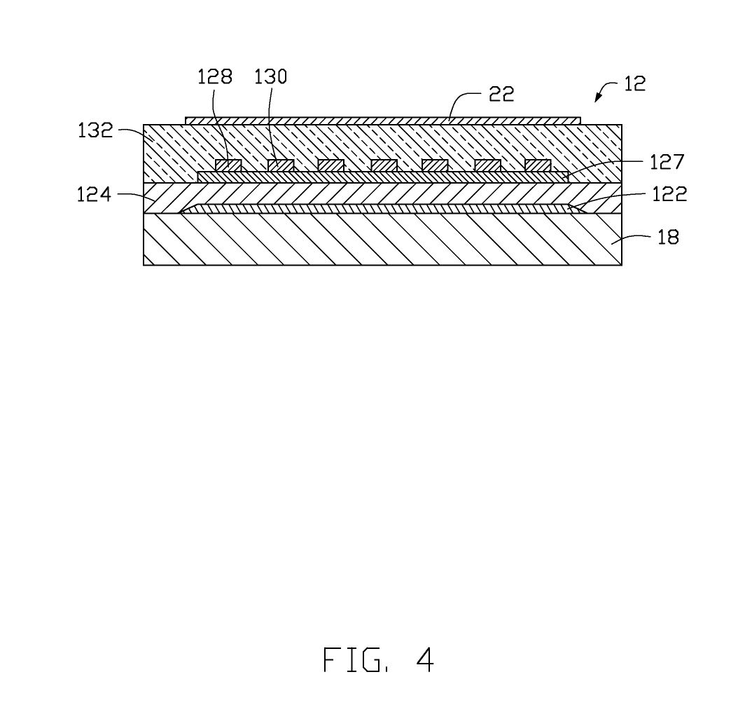

Referring to FIG. 3, a protection layer 22 made of ITO is individually applied to a top of a GOA structure 12 of the GOP. Also referring to FIG. 4, like the GOA structure 12 of the first embodiment, the GOA structure 12 of this embodiment also has a gate electrode 122 formed on a substrate 18. An electrically insulating layer 124 is formed on the substrate 18 to cover the gate electrode 122 therein. A semiconductor layer 127 is formed on the electrically insulating layer 124 and over the gate electrode 122. A source electrode 128 and a drain electrode 130 are formed on the semiconductor layer 127. Each of the source and drain electrodes 128, 130 has a comb-shaped structure (better seen in FIG. 3), including a plurality of teeth interlacing each other. In other words, the teeth of the source and drain electrodes 128, 130 are alternated with each other. As illustrated in FIG. 4, a passivation layer 132 is formed on the electrically insulating layer 124 to cover the semiconductor layer 127 and the source and drain electrodes 128, 130 therein. The protection layer 22 is formed on the passivation layer 132 over the source and drain electrodes 128, 130 and the semiconductor layer 127 to protect them from damage which may be caused by the gold balls and/or fibers in the sealant for combining the TFT array substrate and the color filter substrate together. In this embodiment, the protection layer 22 is located right over the semiconductor layer 27 and the source and drain electrodes 128, 130, has an area slightly larger than an area of the semiconductor layer 127 and does not extend beyond the region occupied by the GOA structure 12.

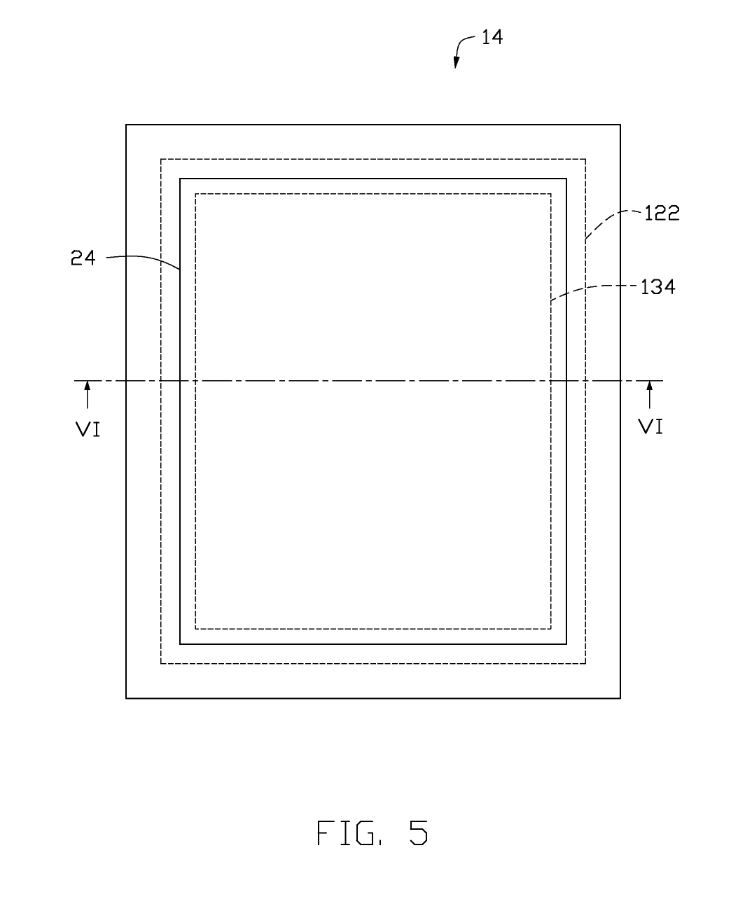

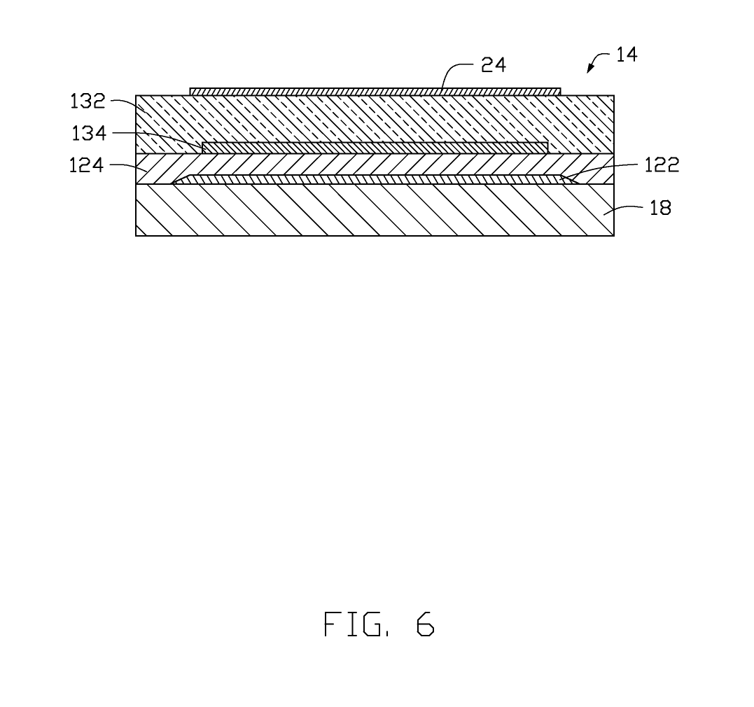

Referring to FIG. 5, a protection layer 24 made of ITO is individually applied to a top of a capacitor 14 of the GOP 10. Also referring to FIG. 6, the capacitor 14 has a substrate 18, a gate electrode 122 on the substrate 18, an electrically insulating layer 124 on the substrate 18 to cover the gate electrode 122 therein, an electrode 134 formed on the electrically insulating layer 124 and over the gate electrode 122, and a passivation layer 132 formed on the electrically insulating layer 124 and covering the electrode 134 therein. The protection layer 24 is formed on the passivation layer 132 and over the electrode 134. The gate electrode 122 and the electrode 134 form the two electrical terminals of the capacitor 14. The protection layer 24 is positioned right over the electrode 134, has an area slightly larger than an area of the electrode 134 and does not extend beyond the region occupied by the capacitor 14.

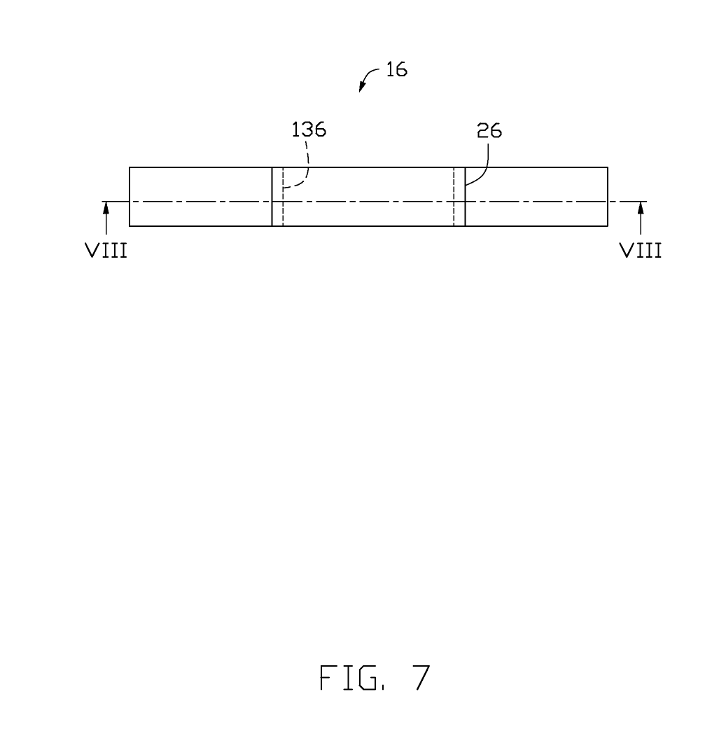

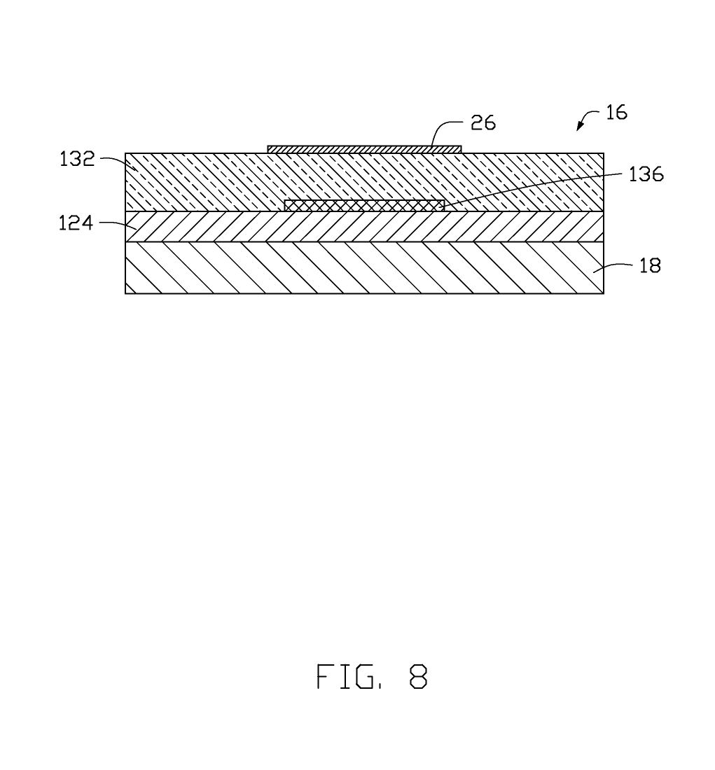

Referring to FIG. 7, a protection layer 26 made of ITO is individually applied to a top of a transmission line 16. Also referring to FIG. 8, the transmission line 16 includes a substrate 18, an electrically insulating layer 124 formed on the substrate 18, an electrically conductive line 136 formed on the electrically insulating layer 124, and a passivation layer 132 formed on the electrically insulating layer 124 and covering the electrically conductive line 136 therein. The protection layer 26 is formed on the passivation layer 132 right over the electrically conductive line 136, has an area slightly larger than an area of the electrically conductive line 136, and does not extend beyond the region occupied by the transmission line 16.

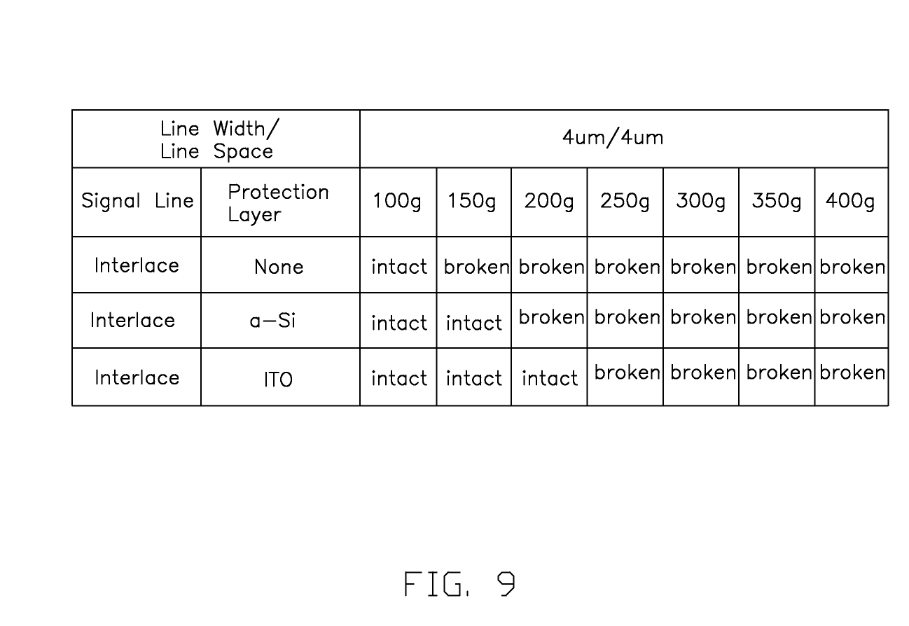

Referring to FIG. 9, a table of a test for verifying the protecting effectiveness of the protection layer 20 (22, 24, 26) in accordance with the present disclosure is shown. The test is conducted to have a pencil scratch across a plurality of electrically conductive lines under predetermined forces. Each electrically conductive line has a width of 4 μm. A space between two neighboring lines is also 4 μm. From the table it can be seen that when the force exerted by the pencil to the electrically conductive lines reaches 150 g and there is no protection layer over the electrically conductive lines, there are electrically conductive lines broken by the scratching action of the pencil. On the other hand, when the electrically conductive lines are covered by an a-Si layer, there are electrically conductive lines broken by the scratching action of the pencil when the force exerted by the pencil to the electrically conductive lines reaches 200 g. When the electrically conductive lines are covered by the protection layer 20 (22, 24, 26) of the present disclosure which is made of ITO, only when the force exerted by the pencil to the electrically conductive lines reaches 250 g, there are electrically conductive lines starting to break.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size and arrangement of parts within the principles of the present disclosure, up to and including the full extent established by the broad general meaning of the terms used in the claims.

What is claimed is:

1. A gate driver on panel (GOP) located at a periphery of a thin film transistor (TFT) array substrate and configured for supplying power and signals to a display area of the TFT array substrate, the GOP comprising:
a plurality of capacitors;
a plurality of gate driver-on-array (GOA) structures;
a plurality of transmission lines electrically connecting the capacitors and GOA structures together; and
at least one electrically conductive protection layer in electrical insulation from the capacitors, the GOA structures and the transmission lines being formed on a top of at least one of the capacitors, the GOA structures and the transmission lines to protect the at least one of the capacitors, the GOA structures and the transmission lines from damage caused by a foreign article.

2. The GOP of claim 1, wherein the at least one protection layer is made of indium tin oxide.

3. The GOP of claim 2, wherein the at least one protection layer covers all of the capacitors, the GOA structures and the transmission lines.

4. The GOP of claim 3, wherein each of the GOA structures comprises at least one gate electrode, an electrically insulating layer covering the at least one gate electrode, a semiconductor layer formed on the electrically insulating layer and over the at least one gate electrode, a source electrode formed on the electrically insulating layer and electrically coupling with an end of the semiconductor layer, a drain electrode formed on the electrically insulating layer and electrically coupling an opposite end of the semiconductor layer, a passivation layer covering the source and drain electrodes and the semiconductor layer, the at least one protection layer being formed on a top of the passivation layer, wherein the source electrode has a part extending through a hole defined in the electrically insulating layer to electrically couple with the at least one gate electrode.

5. The GOP of claim 4, wherein each of the source and drain electrodes is substantially comb-shaped and includes a plurality of teeth, the teeth of the source and drain electrodes interlacing each other.

6. The GOP of claim 3, wherein each of the capacitors comprises a gate electrode, an electrically insulating layer covering the gate electrode therein, an electrode located on the electrically insulating layer and over the gate electrode, and a passivation layer formed on the electrically insulating layer to cover the electrode therein, the at least one protection layer being formed on the passivation layer of each of the capacitors.

7. The GOP of claim 3, wherein each of the transmission lines includes an electrically insulating layer, an electrically conductive line on the electrically insulating layer, and a passivation layer on the electrically insulating layer to cover the electrically conductive line therein, the at least one protection layer being formed on the passivation layer of each of the transmission lines.

8. The GOP of claim 2, wherein the at least one protection layer covers a selected one of the GOA structures, the selected one of the GOA structure comprises at least one gate electrode, an electrically insulating layer covering the at least one gate electrode, a semiconductor layer formed on the electrically insulating layer and over the at least one gate electrode, a source electrode formed on the electrically insulating layer and electrically coupling with an end of the semiconductor layer, a drain electrode formed on the electrically insulating layer and electrically coupling an opposite end of the semiconductor layer, a passivation layer covering the source and drain electrodes and the semiconductor layer, the at least one protection layer being formed on a top of the passivation layer, wherein the source electrode has a part extending through a hole defined in the electrically insulating layer to electrically couple with the at least one gate electrode, and wherein the at least one protection layer does not extend beyond the region occupied by the selected one of the GOA structures.

9. The GOP of claim 8, wherein each of the source and drain electrodes is substantially comb-shaped and includes a plurality of teeth, the teeth of the source and drain electrodes interlacing each other.

10. The GOP of claim 2, the at least one protection layer covers a selected one of the capacitors, the selected one of the capacitors comprises a gate electrode, an electrically insulating layer covering the gate electrode therein, an electrode located on the electrically insulating layer and over the gate electrode, and a passivation layer formed on the electrically insulating layer to cover the electrode therein, the at least one protection layer being formed on the passivation layer of the selected one of the capacitors and does not extend beyond the region occupied by the selected one of the capacitors.

11. The GOP of claim 2, wherein the at least one protection layer covers a selected one of the transmission lines, the selected one of the transmission lines comprises an electrically insulating layer, an electrically conductive line on the electrically insulating layer, and a passivation layer on the electrically insulating layer to cover the electrically conductive line therein, the at least one protection layer being formed on the passivation layer of the selected one of the transmission lines, and the at least one protection layer does not extend beyond the region occupied by the selected one of the transmission lines.
